(19) United States
(12) Patent Application Publication
(10) Pub. No.: US 2008/0206464 A1
(43) Pub. Date: Aug. 28, 2008

(54) Method and Device for the Depositing of Gallium Nitrite Layers on a Sapphire Substrate and Associated Substrate Holder

(75) Inventor: Johannes Kappeler, Wurselen (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: AIXTRON INC., Sunnyvale, CA (US)

(21) Appl. No.: 11/720,604

(22) PCT Filed: Nov. 18, 2005
(86) PCT No.: PCT/EP05/56049

§ 371 Date: May 31, 2007

(30) Foreign Application Priority Data
Dec. 4, 2004 (DE) 10 2004 058 521.0

(51) Int. Cl. B05B 9/00; C23C 16/06

(52) U.S. Cl. 427/255.394; 118/620

(57) ABSTRACT

The invention relates to a device for holding at least one substrate (2) in a process chamber (3) of a reactor housing (15), comprising an attack area (4) for the attack of a handling device and a bearing area (5) upon which the substrate (2) rests with at least the edge (2″) thereof. In order to etch the deposited gallium nitrite layer in relation to the substrate, it is impinged upon with a laser jet from the bottom up. The bearing area (5) is transparent for the wavelength (1) of an optical substrate treatment process.

The invention relates to a device for holding at least one substrate in a process chamber of a reactor housing comprising an engagement zone for the engagement of a handling device and comprising a support zone, on which the substrate rests at least with its periphery.

The invention additionally relates to a coating device, in particular in the form of an MOCVD reactor, preferably an HVPE reactor, comprising a process chamber for depositing layers on at least one substrate held by a substrate holder, which process chamber is brought to process temperature by a heater.

Furthermore, the invention relates to a method for depositing at least one layer on at least one substrate, the substrate being coated at a process temperature on a substrate holder in a process chamber of a reactor housing and then impinged upon by light from below without any significant cooling or heating, in order to at least partially detach the layer from the substrate.

U.S. Pat. No. 6,750,121 B1 describes a method for depositing gallium nitrite layers on a sapphire substrate, the thermal properties of the layer and the substrate being so different that, as a result of different coefficients of thermal expansion, fractures may occur when the layer material deposited at a relatively high process temperature is cooled.

To avoid such fractures, it is proposed by U.S. Pat. No. 6,750,121 B1 that the substrate is treated with laser light from below at substantially the process temperature, the laser light penetrating through the sapphire layer and at least partially detaching the gallium nitrite layer from the substrate surface, so that the fractures otherwise occurring on cooling are avoided. The nitrite layer produced in this way can later be used as a substrate for other coating methods. It is then completely detached from the sapphire substrate in further stages of the process.

DE 12 32 731 discloses a loading and unloading mechanism of a process chamber of a coating device, in which a substrate holder is lifted off a substrate holder carrier by means of a gripper, the substrate holder having an annular form and gripping under the substrate from the periphery.

On the basis of the aforementioned prior art, it is an object of the invention to provide means by which layers can be deposited on substrates in an improved way, the thermal expansion properties of the layer and the substrate being different and it being possible in particular to produce gallium nitrite substrates. It is intended in particular to improve the depositing of one or more thick gallium nitrite layers on a sapphire substrate, which layers can later be detached from the substrates.

The object is achieved first and foremost by the invention specified in the independent claims. The further claims, formally worded as subclaims, represent advantageous developments of the invention not only in combination with the independent claims but also represent solutions in their own right.

The substrate holder is developed according to the invention by the support zone being transparent to the wavelength of the optical substrate treatment process. As a result of this configuration, the optical treatment following the coating can be carried out on one and the same substrate holder. The latter can be transferred from the process chamber into a treatment chamber with a handling device such as that described by DE 10 232 731, the treatment chamber preferably being disposed directly next to the process chamber and kept at substantially the same temperature as the process chamber. It is also possible for the process chamber and the treatment chamber to be merely separated from each other by a dividing wall. The two chambers may also be portions of one and the same space. In a preferred configuration, the substrate holder has an annular form. For this purpose, the substrate holder may have a basic body in the form of a circular ring or annulus. The central free space of this basic body has an outline that is somewhat larger than the surface area of the substrate. As a result of this configuration, the entire substrate surface can be treated from below with a laser beam which impinges on the underside of the substrate through the central free space of the basic body. The support zone is preferably formed by a supporting element resting on the basic body. The supporting element may, however, also be connected to the basic body in some other way. It is important that the supporting element is transparent to the wavelength of the optical substrate treatment process. In this case, the supporting element may be of a one-part or multi-part form. It should, however, have portions that protrude into the central free space, in order in this way to carry the substrate. The supporting element preferably consists of the same material as the substrate, that is to say preferably of sapphire (Al₂O₃). It is also possible for a number of substrates to rest on one substrate holder. For this purpose, the substrate holder may have a multiplicity of openings in the manner of a grid, on the periphery of which the periphery of the substrate rests. Since the supporting element is preferably transparent to the wavelength required for the treatment, it is also possible for the substrate to rest on such a supporting element with its full surface area. However, the supporting element preferably has the form of a circular disk and rests on a step of the basic body. Along with suitable gas inlet devices, the CVD reactor which forms the process chamber also has at least one gas outlet device and a heater for heating up the substrate or the substrate holder or a substrate holder carrier carrying the substrate holder. This heater may be a resistance heater. It may be an infrared heater or an RF heater. In the process chamber there is preferably a substrate holder carrier, on which the substrate holder can be placed by means of a handling device. The substrate holder carrier preferably has a pedestal, over which the annular substrate holder can be slipped in such a way that the supporting element rests on the pedestal. The substrate holder carrier may lie in an opening in the floor of the process chamber. The bottom of this opening has outlet nozzles for gases that form a gas cushion, on which the substrate holder carrier is rotationally driven in a floating manner. The substrate holder carrier is preferably also rotationally driven by the gas emerging from the bottom of the opening. Attached to the process chamber is a treatment chamber. In the latter, the optical aftertreatnent takes place at substantially the same process temperature. For his purpose, the substrate holder with the substrate resting on it is brought to said chamber by means of a handling device. Here, too, the heating may take place from below, in the way described above. The impingement of light on the substrate from below takes place by means of a laser beam at a wavelength of, for example, 355 nm. It may therefore comprise a laser array that lies in a depression in the bottom of the treatment chamber. However, it is also possible to use an individual laser that can be influenced in its direction and scans the complete surface area of the substrate line by line or spirally. The process takes place at the customary process pressures, that is to say in a range between 10 and 1000 hPa. The optical treatment may also take place at these total pressures. The process chamber and the treatment chamber are purged in a suitable way by inert gases such as noble gases or nitrogen or hydrogen. In addition, surface-stabilizing gases such as ammonia may be used.

Exemplary embodiments of the invention are explained below on the basis of accompanying drawings, in which:

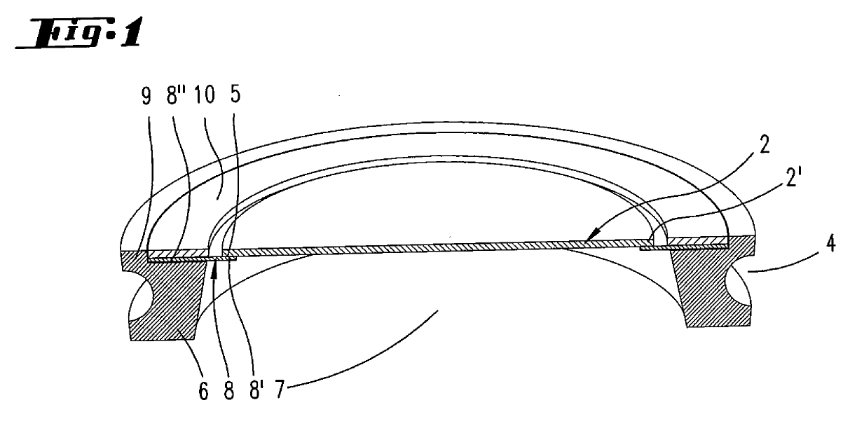

FIG. 1 shows in a half-section in perspective representation a substrate holder of a first exemplary embodiment with a substrate resting on it,

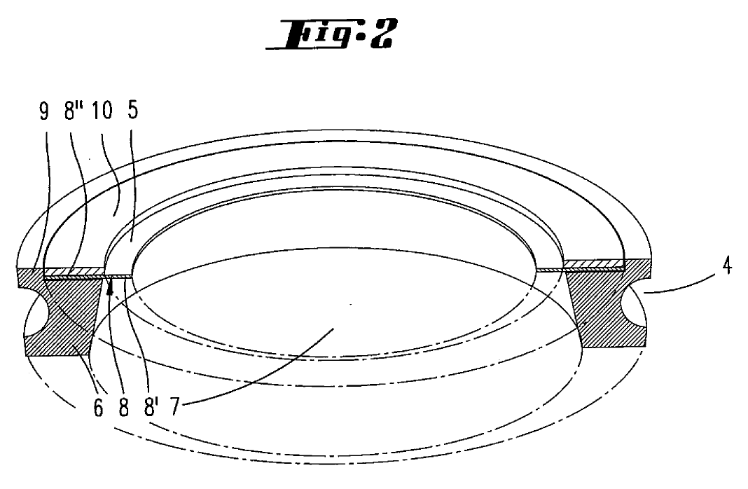

FIG. 2 shows a perspective representation of the substrate holder of the first exemplary embodiment (FIG. 1) without a substrate resting on it,

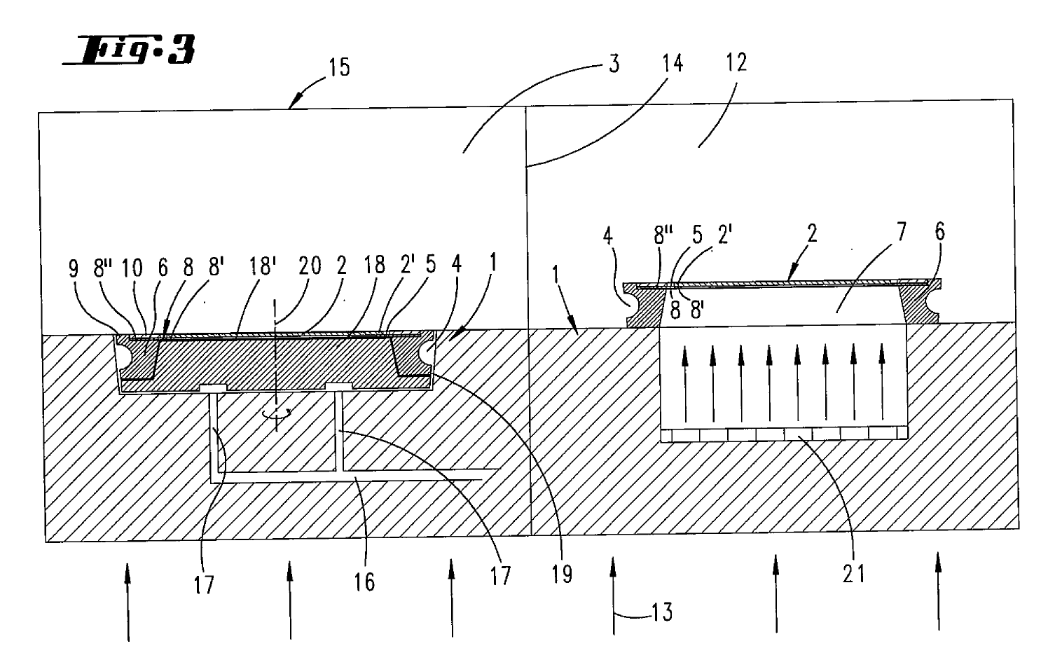

FIG. 3 shows in schematic representation in section a reactor housing with a process chamber and a treatment chamber attached thereto,

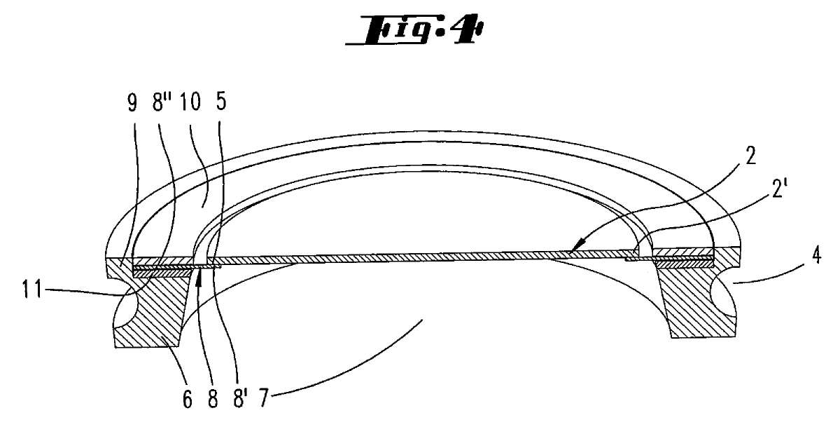

FIG. 4 shows a second exemplary embodiment of a substrate holder in a representation according to FIG. 1,

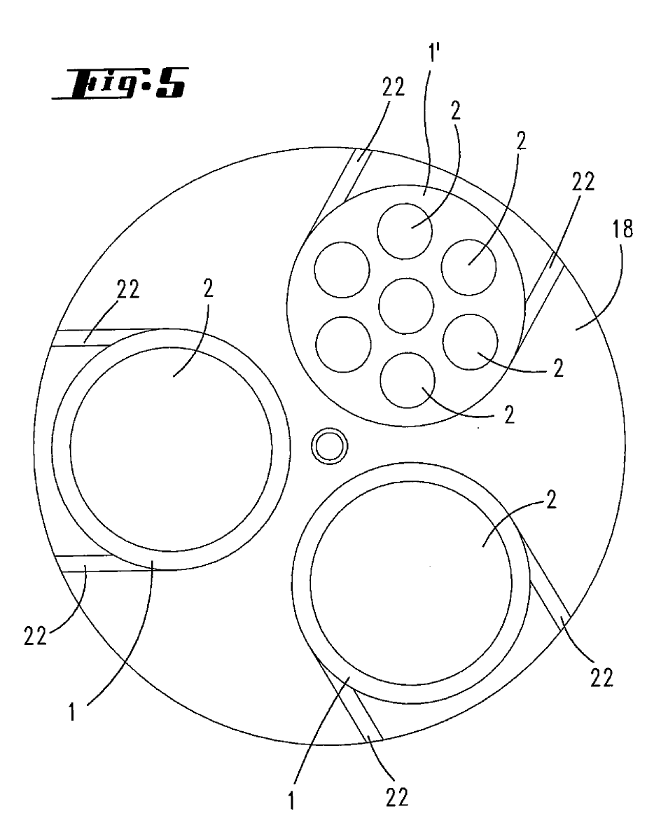

FIG. 5 shows the plan view of a further exemplary embodiment, in which three differently configured substrate holders rest on a substrate holder carrier,

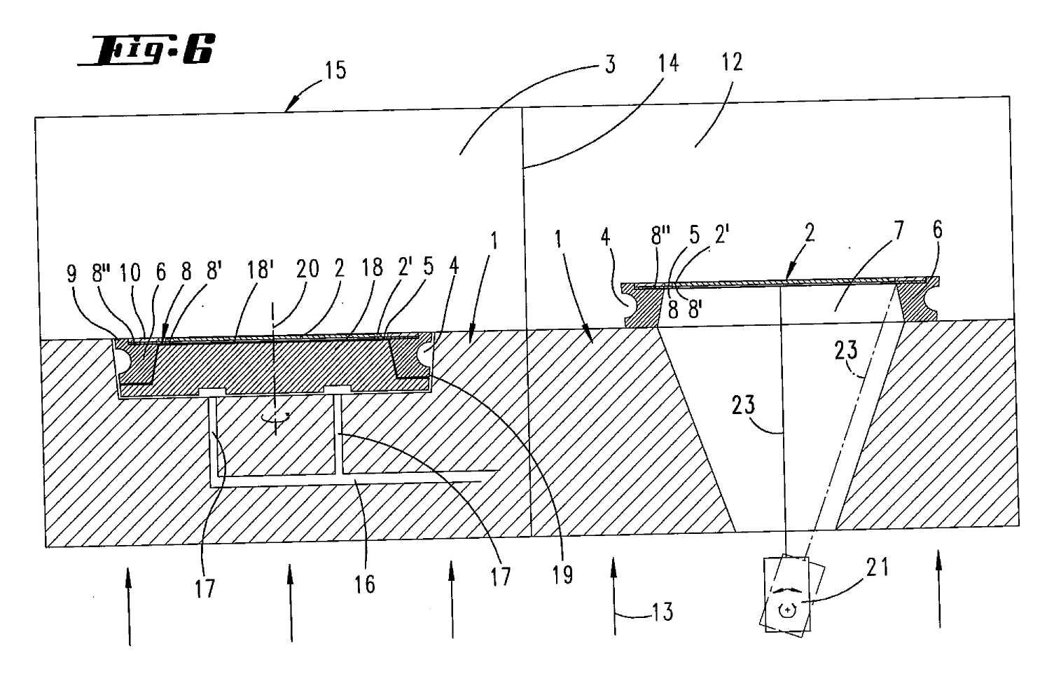

FIG. 6 shows a further exemplary embodiment of the invention in a representation according to FIG. 3,

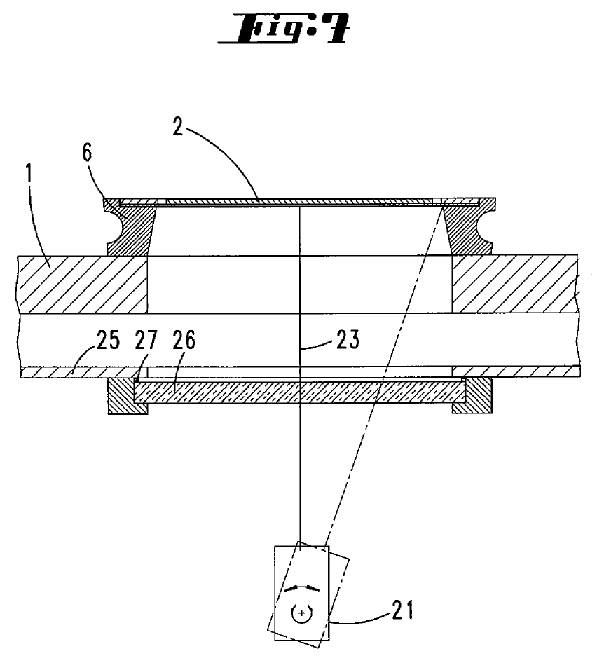

FIG. 7 shows a further exemplary embodiment in a treatment chamber in a representation according to FIG. 3,

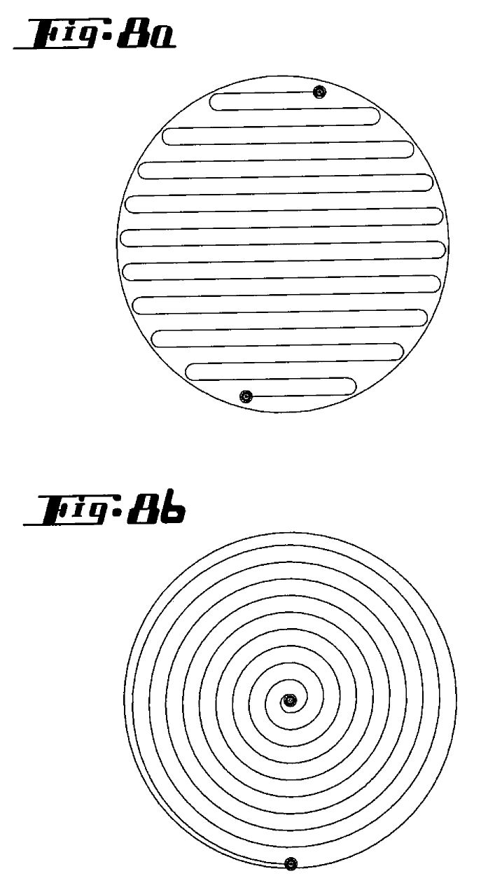

FIG. 8a shows one possible scanning curve of a controllable laser,

FIG. 8b shows a second possible scanning curve of a controllable laser,

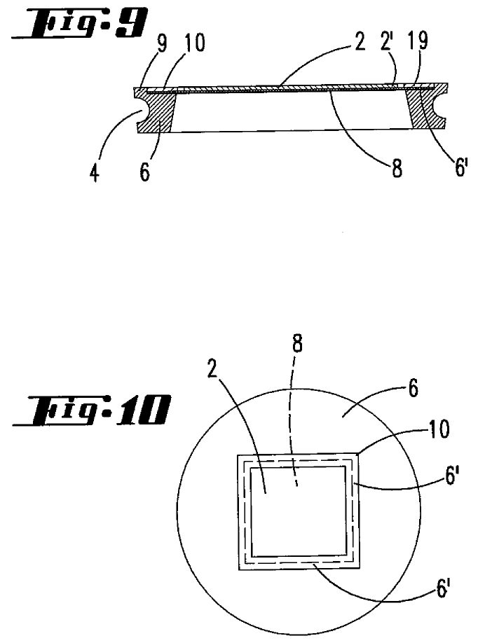

FIG. 9 shows a further exemplary embodiment of a basic body in section, and

FIG. 10 shows a further exemplary embodiment of a basic body with a plan view in a representation according to FIG. 1.

The exemplary embodiment represented in FIG. 1 is a substrate holder 1, which has an annular basic body 6, consisting of SiC, TaC or a pyrolytic BN coated graphite or of quartz glass. This basic body has a circumferential groove on the outer wall, forming an engagement zone for a fork-shaped handling device, as described for example by DE 10 232 731. The inner space 7 of the rotationally symmetrical, annular basic body 6 has a diameter which is greater than the diameter of the substrate 2.

Forming a peripheral rib 9, the upper side of the basic body 6 forms a step. A sapphire body 8, which takes the form of an annular disk and forms a supporting element, lies on this step. The supporting element 8 rests with its outer periphery 8″ on the step. The inner peripheral portion 8′ of the supporting element 8 protrudes into the central free space 7 of the basic body 6.

This periphery 8′, protruding into the free space 7, forms a support zone 5 for the periphery 2′ of the substrate 2. The peripheral rib 9 serves for the centering of the supporting element 8. The peripheral rib 9 is somewhat higher than the material thickness of the supporting element 8 consisting of sapphire, so that an annular disk-shaped graphite or quartz body 10 resting on the periphery 8″ of the supporting element 8 and forming a compensation plate can also be centered. The thickness of this compensation plate 10 corresponds substantially to the thickness of the substrate 2. The compensation plate 10 serves for the centering of the substrate. The inner edge of the annular compensation plate 10 is approximately in line with the inner wall of the basic body 6.

FIG. 3 shows very schematically a reactor housing 15, which has a process chamber 3 and, attached to it, a treatment chamber 12. The process chamber 3 is separated from the treatment chamber 12 by a dividing wall 14.

Gas inlets (not represented) open out into the process chamber 3, in order for example to introduce the reactive gases serving for layer deposition into the process chamber 3. These gases are hydrides and chlorides, preferably gallium chloride and ammonia. Reactions in the gas phase, which may also be plasma-assisted, cause the reactive gases to break down in association with one another or at least be thermally excited so that a gallium-nitrite layer is deposited on the surface of the substrate. The substrate 2 consists of a sapphire. In addition, the process chamber 3 has means (not represented) for discharging the process gas or the reaction products from the process chamber. These means may include a vacuum pump.

The bottom of the process chamber 3 forms a depression 19. Arranged in the bottom of the depression 19 are nozzles 17, which are connected to a gas supply line 16. From the nozzles 17 there exit gas streams, which raise a substrate holder carrier 18 resting in the depression 19 and make it rotate. The substrate holder carrier 18 is preferably produced from coated graphite and forms a pedestal onto which the substrate holder 1 can be placed by means of a handling device (not represented). At the same time, the pedestal of the substrate holder carrier 18 protrudes into the central free space 7 of the basic body 6. The substrate holder 1 and the substrate holder carrier 18, as well as all other elements of the process chamber 3, may be produced from any suitable material that is resistant to high temperatures. In the exemplary embodiment, the inwardly protruding periphery 8′ of the supporting element 8 is supported on the upper side of the pedestal. The basic body 6 lies in an annular recess, which on the one hand forms the wall of the depression 19 and on the other hand forms the outer wall of the pedestal.

By introducing the aforementioned gases and additional carrier gases, such as hydrogen or nitrogen, and heating the process chamber 3, the chemical reaction is initiated.

The heating of the process chamber 13 can take place from all sides. In FIG. 3, the heating is merely indicated by the arrows.

The treatment chamber 12 is provided in the direct vicinity, in particular in the same reactor housing 15. Substantially the same temperature as prevails in the process chamber 3 also prevails in this treatment chamber. However, the temperature inside the treatment chamber may also be lower than the temperature inside the process chamber 3. It is important that the difference in temperature is small enough to avoid the aforementioned damage. However, no reactive gases enter there. A dividing wall 14 keeps them out. However, it is also possible to omit the dividing wall 14.

In the exemplary embodiment, the bottom of the treatment chamber 12 forms a depression. Disposed on the bottom of the depression is a laser arrangement 21, which emits light at a wavelength of 355 nm. Other wavelengths may, however, also be emitted for other processes.

The light emitted by the laser arrangement 21 penetrates through the periphery 8′ of the annular disk 8, consisting of sapphire, and the entire substrate 2, that is to say also that the peripheral portion 2′ of the substrate 2 that is resting on the annular disk. As a result of the light energy introduced, the interface between the substrate and the gallium-nitrite layer applied to it changes in such a way that it softens. This causes the gallium-nitrite layer to be partially detached from the substrate surface. A possible crystalline attachment between the layer and the substrate is destroyed. Amorphous material may be produced in the region of the interface.

It is also provided that, during the optical treatment, the process temperature inside the treatment chamber 12 is lowered further from a temperature that lies below the process temperature.

To carry out the method, firstly the substrate holder with the substrate resting on it is introduced into the process chamber 3. There, a gallium-nitrite layer several micrometers thick is applied in the way known per se to the substrate 2 consisting of sapphire. Then a handling device is used to bring the substrate holder with the substrate 2 resting on it into the treatment chamber 12, where the substrate 2 is impinged from below with laser light, in order that the gallium-nitrite layer is detached from the sapphire substrate. Both processes can be carried out substantially at the same process temperature of approximately 1000 or 1100° C.

Then, the substrate holder 1 with the substrate 2 resting on it is removed from the treatment chamber 12 by means of a handling device and cooled. During the cooling, the layer can shift with respect to the substrate in a lateral direction, so that no fracturing occurs.

In the case of the further exemplary embodiment represented in FIG. 4, lying under the annular disk 8 there is also an underlay plate, which takes the form of an annular disk and lies on the step formed by the basic body.

In the case of the exemplary embodiment represented in FIG. 5, the substrate holder carrier 18 carries a total of three substrate holders 1, 1′. The substrate holders 1 have the shape described above. The substrate holder 1′ is differently shaped. It is capable of carrying a multiplicity of substrates 2.

The fork-shaped handling device gains access via channels 22, as described in DE 10 232 731.

In the case of the exemplary embodiment represented in FIG. 6, the treatment chamber 2 has a bottom with a funnel-shaped opening. In the inlet region of the funnel-shaped opening there is a positionable laser 21. This can be pivoted about various pivot axes, in order to scan the underside of the substrate with its laser beam 23.

In the case of the exemplary embodiment represented in FIG. 7, the reactor wall 25 disposed underneath the substrate holder 1 has an opening, which is closed off by a window 26, which is supported on a frame 28, with interposition of a seal 27. Underneath the window 26, that is to say outside the actual process chamber or reactor chamber, in which there may be a vacuum, is the laser arrangement 21. Here, too, this may be a pivotable laser, the laser beam 23 of which can scan the underside of the substrate, in order in this way to detach the thick gallium-nitrite layer from the transparent substrate.

The laser may in this case scan the underside of the substrate line by line, as represented in FIG. 8a. However, it is also possible for the underside of the substrate to be scanned spirally, as represented in FIG. 5b. This may take place from the inside outward or from the outside inward. The scanning preferably takes place from the outside inward. And the temperature may even be lowered at the same time.

In the case of the exemplary embodiment represented in FIG. 9, the supporting element 8 takes the form of an annular disk. It is transparent to the laser beam used, the wavelength of which is for example 355 nm. It completely supports the substrate 2, since it has the form of a circular disk.

The exemplary embodiment of a basic body 6 represented in FIG. 10 shows a square opening with a step 6′, on which a correspondingly shaped supporting element 8 may be placed, so that both round and angular substrates can be treated with this device. Here, too, as in the case of the exemplary embodiment represented in FIG. 9, a compensation plate 10 may be provided, centering the substrate in its position on the supporting element 8.

All disclosed features are (in themselves) pertinent to the invention. The disclosure content of the associated/accompanying priority documents (copy of the prior patent application) is also hereby incorporated in full in the disclosure of the application, including for the purpose of incorporating features of these documents in claims of the present application.

What is claimed:

1. A system, comprising:
device for holding at least one substrate (2), the device having an engagement zone (4) for the engagement of a handling device, and a support zone (5), configured for the substrate (2) rests at least with its periphery (2′), the support zone (5) being transparent to a wavelength of light used in an optical substrate treatment process;
and a light source (21) disposed underneath the device and configured to provide light of the wavelength for the optical substrate treatment process.

2. The system as in claim 1, wherein the device is characterized by an annular form.

3. The system as in claim 1, wherein the devicee has an annular basic body (6), with a central free space (7) of which in outline is surrounded by the substrate (2) when the substrate rests on the support zone (5).

4. The system as in claim 1, wherein the device further comprises at least one supporting element (8), which rests on a basic body (6), and forms the support zone (5), the support element made of material that is transparent to the wavelength of light used in the optical substrate treatment process.

5. The system as claimed in claim 4, wherein one or more portions (8′) of the supporting elements (8) extends into or over a central free space (7) of the device.

6. The system as in claim 4, wherein the supporting element (8) consists of a same material as the substrate (2).

7. The in claim 1, wherein the device is configured to accommodate multiple substrates.

8. The as in claim 4, wherein the supporting element (8) takes the form of an annular disk and rests on a step of a basic body (6) of the device.

9. The system as in claim 4, wherein the supporting element (8) consists of sapphire (Al₂O₃).

10. A device for coating a substrate comprising: a process chamber (3) for depositing layers on at least one substrate (2) held by a substrate holder (1), which process chamber (3) is brought to process temperature by a heater (13); and a treatment chamber (12) attached to the process chamber (3) for optical after treatment at substantially a same or a somewhat lower process temperature of the at least one substrate (2) brought there on the substrate holder (1).

11. The device as in claim 10 characterized in that, in the process chamber (3), the substrate holder (1) rests on a substrate holder carrier (18), which can be heated from below.

12. The device as characterized in that the substrate holder carrier (18) is mounted in a rotationally driven manner, over gas jets configured to provide a gas cushion.

13. The device as claimed in claim 11, wherein the substrate holder (1) includes at least one supporting element (8), which rests on a body (6) and forms a support zone (5) for the substrate (2), the support zone being transparent to a wavelength of light used in an optical substrate treatment Process within the treatment chamber (12), characterized in that the supporting element (8) rests on the substrate holder carrier (18).

14. The device as in claim 13, characterized in that the treatment chamber (12) has a laser arrangement (21) as a light source.

15. The device as in claim 14, characterized in that the laser arrangement (21) emits a light at a wavelength of 355 nm.

16. A method for depositing at least one layer on at least one substrate (2), comprising: coating the substance at a process temperature in a process chamber (3) of a reactor housing (15) while resting on a substrate holder (1), and then light upon the substrate from below without significant cooling, or with slight cooling, in a treatment chamber (12) while resting on the same substrate holder (1), in order to influence the interface between the layer and the substrate (2) and possibly partially detach said layer.

17. The method as in claim 16 or in particular according characterized in that the process temperature is one of: greater than 900° C., greater than 1000° C. or greater than 1100° C.

18. The method as in claim 16, characterized in that the layer is a gallium-nitrite layer several micrometers thick, and the substrate is a sapphire substrate.

19. The method in claim 16, characterized in that the deposition takes place by reactive gases introduced into the process chamber (3).

20. The method as claim 19, in characterized in that the gases introduced into the process chamber comprise elements of the third and fifth or second and sixth main groups.

21. The method as in claim 19, characterized in that the reactive gases introduced into the process chamber (3) are chlorides and hydrides.

22. The method as in claim 19, characterized in that gallium chloride and NH₃ are introduced into the process chamber for the growth of gallium nitrite.

23. The device as in claim 4, wherein the supporting element (8) is in the form of a circular disk.
